(19) United States
(12) Patent Application Publication
(10) Pub. No.: US 2026/0206252 A1
(43) Pub. Date: Jul. 16, 2026

(54) BOTTOM U-SHAPED GATE-ALL-AROUND TRANSISTOR DEVICE AND MANUFACTURING METHOD THEREFOR, AND DEVICE AND MANUFACTURING METHOD THEREFOR

(71) Applicants: FUDAN UNIVERSITY, Shanghai (CN); SHANGHAI INTEGRATED CIRCUIT MANUFACTURING INNOVATION CENTER CO., LTD., Shanghai (CN)

(72) Inventors: Chunlei WU, Shanghai (CN); Yumin XU, Shanghai (CN); Boqian SHEN, Shanghai (CN); Fei ZHAO, Shanghai (CN); Zichen YANG, Shanghai (CN); Wei ZHANG, Shanghai (CN)

(21) Appl. No.: 19/138,044

(22) PCT Filed: May 31, 2023
(86) PCT No.: PCT/CN2023/097395

§ 371 Date: Jun. 11, 2025

(51) Int. Cl. H10D 30/00; H10D 30/01; H10D 30/43; H10D 62/10; H10D 64/01

(52) U.S. Cl. CPC H10D 30/502; H10D 30/014; H10D 30/0191; H10D 30/43; H10D 62/103; H10D 62/121; H10D 64/017

(57) ABSTRACT

A bottom U-shaped gate-all-around transistor device, including: a substrate, a first source region, a first drain region, a first control gate, a first channel layer, a second source region formed between the substrate and the first source region and a second drain region formed between the substrate and the first drain region, a thickness of a first control gate in a second direction is greater than thicknesses of other control gates in the second direction, a height of a first surface of the second source region and a height of a first surface of the second drain region in the second direction are not higher than a bottom surface of the first channel layer, a second surface of the second source region and a second surface of the second drain region are not lower than a surface of the substrate between the second source region and the second drain region.

### TECHNICAL FIELD

The present invention relates to the field of semiconductor devices, and in particular, to a bottom U-shaped gate-all-around transistor device and a manufacturing method therefor, and a device and a manufacturing method therefor.

### BACKGROUND

Compared to a FinFET, a gate-all-around (GAA) stacked nanosheet field-effect transistor (NSFET) is widely used in the development of an integrated technology and the improvement of power performance due to superior electrostatic performance and higher layout efficiency. However, power consumption of a device is still one of the important challenges in a process of miniaturizing a size of the device. One method for reducing power consumption of a gate-all-around transistor device is to reduce leakage in a bottom parasitic channel. Unlike the FinFET, a GAA nanosheet has a wider three-gate bottom channel, which means problems of weaker gate control and bottom leakage. How to suppress an off-state leakage current and direct source-to-drain tunneling has become one of the key challenges in the optimization of the gate-all-around transistor device. Currently, the bottom leakage current is suppressed mainly in a manner of punch through stopping (PTS) ion implantation or bottom dielectric isolation (BDI). However, as the device continues to scale down, a process difficulty of the PTS solution increases constantly and is very sensitive to process fluctuation. In the BDI solution, a dielectric is used to block a bottom parasitic leakage channel, but the introduction of a dielectric layer also poses a greater challenge to a subsequent process.

Therefore, proposing a novel gate-all-around transistor structure that can enhance an effect of suppressing a leakage current while effectively preventing direct source-to-drain tunneling in a bottom tunneling transistor becomes an urgent technical priority for a person skilled

### SUMMARY

The present invention provides a bottom U-shaped gate-all-around transistor device and a manufacturing method therefor, and a device and a manufacturing method therefor, to solve a problem of direct source-to-drain tunneling in a gate-all-around transistor based on a hybrid conduction mechanism while preventing leakage in a bottom parasitic channel.

According to a first aspect of the present invention, a bottom U-shaped gate-all-around transistor device is provided, including:
a gate-all-around MOSFET device including a substrate, a first source region, a first drain region, a first control gate, and channel layers, where the first source region and the first drain region are arranged in a first direction, the first source region and the first drain region are doped with first ions, the first direction represents a direction parallel to a surface of the substrate, the channel layers include a first channel layer, the first channel layer represents a channel layer that is the closest to the substrate, and the first control gate represents a control gate that is the closest to the substrate; and
a second source region and a second drain region, where the second source region is formed between the substrate and the first source region, the second drain region is formed between the substrate and the first drain region, the second drain region is doped with the first ions, the second source region is doped with second ions, and a type of the first ion is different from a type of the second ion; where
a thickness of the first control gate in a second direction is greater than thicknesses of other control gates in the second direction, a height of a first surface of the second source region and a height of a first surface of the second drain region in the second direction are not higher than a bottom surface of the first channel layer, a height of a second surface of the second source region and a height of a second surface of the second drain region in the second direction are not lower than the surface of the substrate between the second source region and the second drain region, and the second direction is perpendicular to the first direction.

Optionally, a length of a channel of the bottom U-shaped gate-all-around transistor device is 5 nm to 100 nm.

Optionally, the thickness of the first control gate in the second direction is 5 nm to 200 nm.

Optionally, a thickness of the second source region and/or the second drain region in the second direction is 5 nm to 50 nm.

Optionally, the gate-all-around MOSFET device further includes:
gate dielectric layers and control gates,
wherein each of the gate dielectric layers wraps a part of a surface of each corresponding channel layer and one of the gate dielectric layers covers the surface of the substrate between the second source region and the second drain region, the channel layers are formed between the first source region and the first drain region and are arranged at intervals in a direction away from the substrate, each of the control gates covers a surface of each corresponding gate dielectric layer, the control gates comprise the first control gate, and when other control gates cover the surfaces of the gate dielectric layers, the first control gate covers the surface of the gate dielectric layer on the surface of the substrate;
inner spacer formed on the surfaces of the channel layers between the first source region and the gate dielectric layers and between the first drain region and the gate dielectric layers;
a source metal layer, a gate metal layer, and a drain metal layer, wherein the source metal layer and the drain metal layer are respectively formed on a surface of the first source region and a surface of the first drain region, and completely wrap the first source region and the second source region and completely wrap the first drain region and the second drain region, respectively, and the gate metal layer is formed at a top end of a top control gate;
an interlayer dielectric layer covering a surface of the source metal layer, a surface of the gate metal layer, a surface of the drain metal layer, and a surface of the inner spacer; and
several metal contact layers penetrating the interlayer dielectric layer and respectively connected to the source metal layer, the gate metal layer, and the drain metal layer.

According to a second aspect of the present invention, a manufacturing method for a bottom U-shaped gate-all-around transistor device is provided, and the method is used to manufacture the bottom U-shaped gate-all-around transistor device according to any implementation of the first aspect of the present invention, and includes:
forming the gate-all-around MOSFET device, the second source region, and the second drain region, where the gate-all-around MOSFET device includes the substrate, the first source region, the first drain region, the first control gate, and the channel layers, the channel layers include a first channel layer, the first channel layer represents a channel layer that is the closest to the substrate, the first control gate represents a control gate that is the closest to the substrate, the first source region and the first drain region are doped with the first ions, the second source region and the second drain region are respectively formed between the substrate and the first source region and between the substrate and the first drain region, the second drain region is doped with the first ions, and the second source region is doped with the second ions; where
a thickness of the first control gate in the second direction is greater than thicknesses of other control gates in the second direction, a height of a first surface of the second source region and a height of a first surface of the second drain region in the second direction are not higher than a bottom surface of the first channel layer, and a height of a second surface of the second source region and a height of a second surface of the second drain region in the second direction are not lower than the surface of the substrate between the second source region and the second drain region.

Optionally, the forming the gate-all-around MOSFET device, the second source region, and the second drain region specifically includes:
providing the substrate;
forming sacrificial layers and the channel layers, where the sacrificial layers and the channel layers are alternately stacked on the substrate, a thickness of a first sacrificial layer is greater than a thickness of another sacrificial layer, and the first sacrificial layer represents a sacrificial layer that is the closest to the substrate;
etching the sacrificial layers and the channel layers to form a fin structure;
forming a dummy gate structure and etching both ends of the sacrificial layers in the first direction to form a cavity of an inner spacer;
forming the inner spacer, where the inner spacer is formed in the cavity of the inner spacer;
forming the second source region and the second drain region, where the second source region and the second drain region are respectively formed on both sides of the fin structure in the first direction;
forming the first source region and the first drain region, where the first source region and the first drain region are respectively formed at a top end of the second source region and a top end of the second drain region;
removing the dummy gate structure and releasing the channel layers; and
forming the gate dielectric layer, the control gates, the source metal layer, the gate metal layer, the drain metal layer, the interlayer dielectric layer, and the metal contact layers.

Optionally, the thickness of the first sacrificial layer is 5 nm to 200 nm, and the thickness of the another sacrificial layer is 5 nm to 50 nm.

Optionally, if the substrate on both sides of the fin structure in the first direction is over-etched when the sacrificial layers and the channel layers are etched to form the fin structure, before the forming the second source region and the second drain region, the method further includes:
forming a first epitaxial layer, where the first epitaxial layer is formed on both sides of the fin structure in the first direction, and a height of the first epitaxial layer in the second direction is not lower than a height of the substrate between the second source region and the second drain region; where
the second source region and the second drain region are separately formed on a surface of the first epitaxial layer.

Optionally, when the sacrificial layers and the channel layers are etched to form the fin structure, an over-etching thickness of the substrate is controlled to range from 5 nm to 100 nm.

According to a third aspect of the present invention, an electronic device is provided, including the bottom U-shaped gate-all-around transistor device according to any implementation of the first aspect of the present invention.

According to a fourth aspect of the present invention, a manufacturing method for an electronic device is provided, including the manufacturing method for a bottom U-shaped gate-all-around transistor device according to any implementation of the second aspect of the present invention.

The present invention provides a bottom U-shaped gate-all-around transistor device. A thickness of a bottom control gate (that is, a first control gate) in a second direction is designed to be greater than thicknesses of other control gates in the second direction. In addition, a height of a first surface of a second source region and a height of a first surface of a second drain region in the second direction are not higher than a bottom surface of a first channel layer, and a height of a second surface of the second source region and a height of a second surface of the second drain region in the second direction are not lower than a surface of a substrate between the second source region and the second drain region. The second direction is perpendicular to a first direction. In this way, in an off state, the second source region at the bottom, the substrate at the bottom, and the second drain region form a P-i-N structure, and an off-state leakage current in a bottom TFET channel is a reverse-biased P-i-N current, so that leakage in a bottom parasitic channel of a conventional gate-all-around transistor device can be significantly suppressed, and a current on-off ratio of the device can be increased. More importantly, at an extremely small size, in a conventional gate-all-around transistor, a direct source-to-drain tunneling case may occur in a bottom TFET channel. A design using a U-shaped gate (that is, the first control gate) can increase a length of an effective channel, so as to prevent direct source-to-drain tunneling. It can be learned that, in the technical solution provided in the present invention, the thickness of the first control gate in the second direction is designed to be higher than the thickness of another control gate in the second direction while preventing leakage in the bottom parasitic channel, so that a problem of direct source-to-drain tunneling in a gate-all-around transistor based on a hybrid conduction mechanism is solved.

### BRIEF DESCRIPTION OF DRAWINGS

To describe the technical solutions in the embodiments of the present invention or the conventional technology more clearly, the following briefly describes the accompanying drawings needed for describing the embodiments or the conventional technology. Clearly, the accompanying drawings in the following descriptions show merely some embodiments of the present invention, and a person of ordinary skill in the art can still derive other accompanying drawings from these accompanying drawings without creative efforts.

FIG. 1 is a schematic diagram of a structure of a device manufactured based on a manufacturing method for a bottom U-shaped gate-all-around transistor device according to a specific implementation of the present invention;

FIG. 2 is a schematic diagram of a structure of a device manufactured based on a manufacturing method for a bottom U-shaped gate-all-around transistor device according to another specific implementation of the present invention;

FIG. 3 is a schematic flowchart of a manufacturing method for a bottom U-shaped gate-all-around transistor device according to a specific implementation of the present invention;

FIG. 4 is a schematic diagram 1 of a structure of a device at different process stages that is manufactured based on a manufacturing method for a bottom U-shaped gate-all-around transistor device according to a specific implementation of the present invention;

FIG. 5 is a schematic diagram 2 of a structure of a device at different process stages that is manufactured based on a manufacturing method for a bottom U-shaped gate-all-around transistor device according to a specific implementation of the present invention;

FIG. 6 is a schematic diagram 3 of a structure of a device at different process stages that is manufactured based on a manufacturing method for a bottom U-shaped gate-all-around transistor device according to a specific implementation of the present invention;

FIG. 7 is a schematic diagram 1 of a structure of a device at different process stages that is manufactured based on a manufacturing method for a bottom U-shaped gate-all-around transistor device according to another specific implementation of the present invention;

FIG. 8 is a schematic diagram 2 of a structure of a device at different process stages that is manufactured based on a manufacturing method for a bottom U-shaped gate-all-around transistor device according to another specific implementation of the present invention; and

FIG. 9 is a schematic diagram 3 of a structure of a device at different process stages that is manufactured based on a manufacturing method for a bottom U-shaped gate-all-around transistor device according to another specific implementation of the present invention.

101—Substrate;

102—Sacrificial layer;

103—Channel layer;

104—Inner spacer;

105—Dummy gate structure;

106—First epitaxial layer;

107—Second source region;

108—Second drain region;

109—First source region;

110—First drain region;

111—Source metal layer;

112—Drain metal layer;

113—Gate metal layer;

114—Interlayer dielectric layer;

115—Metal contact layer.

### DESCRIPTION OF EMBODIMENTS

The technical solutions in embodiments of the present invention are clearly and completely described below with reference to the accompanying drawings in the embodiments of the present invention. Clearly, the described embodiments are merely some rather than all of the embodiments of the present invention. All other embodiments obtained by a person of ordinary skill in the art based on the embodiments of the present invention without creative efforts shall fall within the protection scope of the present invention.

The terms “first”, “second”, “third”, “fourth”, and the like (if they exist) in the specification and claims of the present invention are used to distinguish between similar objects instead of describing a specific sequence or order. It should be understood that data used in this way may be interchangeable in proper circumstances, so that the embodiments of the present invention described herein can be implemented in a sequence other than those shown or described herein. In addition, the terms “include”, “have”, and any variants thereof are intended to cover non-exclusive inclusion, for example, processes, methods, systems, products, or devices including a series of steps or units are not necessarily limited to those steps or units that are clearly listed, but may include other steps or units that are not clearly listed or are inherent to these processes, methods, products, or devices.

How to suppress an off-state leakage current in a gate-all-around (GAA) stacked nanosheet field-effect transistor (NSFET) and the occurrence of a direct source-to-drain tunneling case in a bottom TFET at an extremely small size becomes one of the key challenges in the optimization of the gate-all-around transistor device.

In view of this, the inventors of this application have designed a bottom U-shaped gate-all-around transistor device. This device structure not only increases asymmetrically doped bottom source and drain regions at a location of an original region in which a source and a drain are over-etched, but a doping type of a bottom source region is opposite to that of a source region, and a doping type of a bottom drain region is the same as that of a drain region. A bottom substrate is intrinsic silicon, and a tunneling field-effect transistor of a P-i-N structure is formed in a bottom channel, to suppress a bottom leakage current. In addition, according to the gate-all-around transistor device provided in the present invention, a bottom U-shaped gate is disposed between the bottom source region and the bottom drain region, so that a length of an effective channel is increased, and therefore, direct source-to-drain tunneling can be further prevented.

It can be learned that, in the technical solution provided in this application, in an off state, an off-state leakage current in a bottom TFET channel is a reverse-biased P-i-N current, so that a problem of leakage in a bottom parasitic channel of a conventional gate-all-around transistor device can be significantly suppressed, and a current on-off ratio of the device can be increased.

At an extremely small size, a direct source-to-drain tunneling case may occur in a bottom TFET. If a design of the U-shaped gate is used, a length of an effective channel can be increased, and direct source-to-drain tunneling can be prevented.

The technical solutions of the present invention are described below in detail by using specific embodiments. The following specific embodiments may be combined with each other, and same or similar concepts or processes may not be described repeatedly in some embodiments.

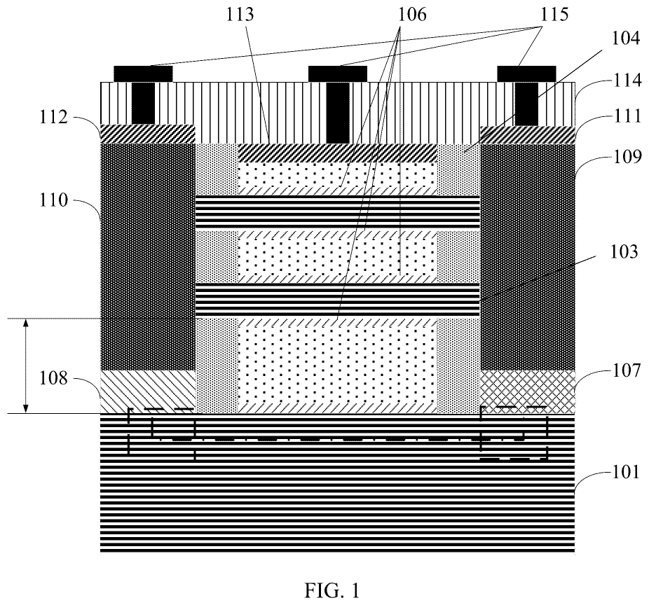

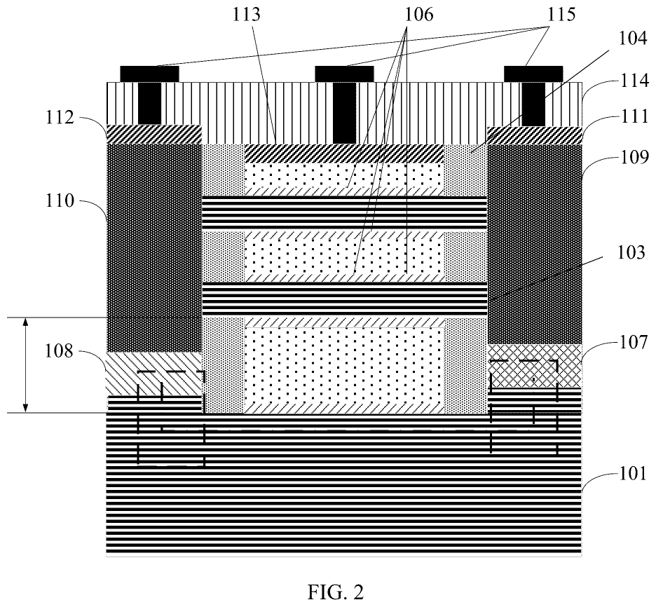

As shown in FIG. 1 to FIG. 9, according to an embodiment of the present invention, a bottom U-shaped gate-all-around transistor device is provided, and includes:
a gate-all-around MOSFET device including a substrate 101, a first source region 109, a first drain region 110, a first control gate, and channel layers 103, where the first source region 109 and the first drain region 110 are arranged in a first direction, the first source region 109 and the first drain region 110 are doped with first ions, the first direction represents a direction parallel to a surface of the substrate 101, the channel layers 103 include a first channel layer 103, the first channel layer 103 represents a channel layer 103 that is the closest to the substrate 101, and the first control gate represents a control gate that is the closest to the substrate 101; and
a second source region 107 and a second drain region 108, where the second source region 107 is formed between the substrate 101 and the first source region 109, the second drain region 108 is formed between the substrate 101 and the first drain region 110, the second drain region 108 is doped with the first ions, the second source region 107 is doped with second ions, and a type of the first ion is different from a type of the second ion; where
a thickness of the first control gate 103 in the second direction is greater than thicknesses of other control gates 103 in the second direction, a height of a first surface of the second source region 107 and a height of a first surface of the second drain region 108 in the second direction are not higher than a bottom surface of the first channel layer 103, a height of a second surface of the second source region 107 and a height of a second surface of the second drain region 108 in the second direction are not lower than the surface of the substrate 101 between the second source region 107 and the second drain region 108, the second direction is perpendicular to the first direction, and the bottom U-shaped gate-all-around transistor device is shown in FIG. 1 or FIG. 2.

The first direction refers to a horizontal direction on the paper, and the second direction refers to a vertical direction on the paper. The first surface of the second source region 107 and the first surface of the second drain region 108 refer to surfaces of the second source region 107 and the second drain region 108 away from the substrate 101. The second surface of the second source region 107 and the second surface of the second drain region 108 refer to surfaces that are of the second source region 107 and the second drain region 108 and that are in direct contact with the substrate 101.

In one aspect, if the height of the second surface of the second source region 107 and the height of the second surface of the second drain region 108 in the second direction are lower than the surface of the substrate 101 between the second source region 107 and the second drain region 108, a length of a bottom effective channel (as shown by a dash-dot path in FIG. 1 or FIG. 2) is shortened, and direct source-to-drain tunneling cannot be prevented at an extremely small size.

In another aspect, if the height of the first surface of the second source region 107 and the height of the first surface of the second drain region 108 in the second direction are higher than the bottom surface of the first channel layer 103, the bottom second source region 107 and the bottom second drain region 108 affect the channel layer 103 on an upper layer, resulting in a decrease in an on-state current of the device.

The first direction refers to a horizontal direction on the paper, and the second direction refers to a vertical direction on the paper. The first surface of the second source region 107 and the first surface of the second drain region 108 refer to surfaces of the second source region 107 and the second drain region 108 away from the substrate 101. The second surface of the second source region 107 and the second surface of the second drain region 108 refer to surfaces in direct contact with the substrate 101.

In the bottom U-shaped gate-all-around transistor device provided in the present invention, a thickness of a bottom control gate (that is, a first control gate) in a gate-all-around transistor based on a hybrid conduction mechanism in the second direction is designed to be greater than thicknesses of other control gates in the second direction. In addition, a height of a surface of the second source region 107 and a height of a surface of the second drain region 108 away from the substrate 101 in the second direction are not higher than the bottom surface of the first channel layer 103, and a height of a surface of the second source region 107 and a height of a surface of the second drain region 108 close to the substrate 101 in the second direction are not lower than the surface of the substrate 101 between the second source region 107 and the second drain region 108. In an off state, the bottom second source region 107, the bottom substrate 101, and the second drain region 108 form a P-i-N structure. Therefore, an off-state leakage current in a bottom TFET channel is a reverse-biased P-i-N current, so that a problem of leakage in a bottom parasitic channel of a conventional gate-all-around transistor device can be significantly suppressed, and a current on-off ratio of the device can be increased. More importantly, at an extremely small size, in a conventional gate-all-around transistor based on a hybrid conduction mechanism, a direct source-to-drain tunneling case may occur in a bottom TFET channel. If a design of a U-shaped gate (that is, the first control gate) is used, a length of an effective channel can be increased (an increased channel length is shown by a dashed-line box part in FIG. 1 or FIG. 2), so as to prevent direct source-to-drain tunneling.

It can be learned that, according to the technical solution provided in the present invention, the thickness of the bottom control gate (that is, the first control gate) in the conventional gate-all-around transistor based on the hybrid conduction mechanism is designed to be greater than the thickness of another control gate in the second direction, so that a problem of direct source-to-drain tunneling in the gate-all-around transistor based on the hybrid conduction mechanism is solved.

The gate-all-around transistor based on the hybrid conduction mechanism refers to a gate-all-around transistor formed after the second source region 107 and the second drain region 108 are added. A reverse-biased P-I-N channel is formed at the bottom of the transistor, and this structure can significantly suppress a leakage current in a bottom parasitic channel of a conventional gate-all-around MOSFET device, thereby increasing a current on-off ratio of the device. Further, because the second source region 107 and the second drain region 108 are added, which are equivalent to connecting a structure of a tunneling field-effect transistor TFET device in parallel at the bottom of the conventional gate-all-around MOSFET device, hybrid conduction of a diffusion-drift current in a gate-all-around channel and a quantum mechanical band-to-band tunneling current in a bottom channel can be implemented, thereby obtaining an ultra-steep on/off characteristic of sub-60 m V/dec. In addition, conduction of the gate-all-around MOSFET device connected in parallel on an upper layer can provide a high current for the device.

The technical solution provided in the present invention aims to increase the length of the effective channel by disposing the first control gate, so as to prevent a case of direct source-to-drain tunneling that may occur in the bottom TFET channel in the conventional gate-all-around transistor based on the hybrid conduction mechanism at an extremely small size.

In an embodiment, a length of a channel of the bottom U-shaped gate-all-around transistor device is 5 nm to 100 nm.

As for an absolute thickness of the first control gate, if the thickness of the first control gate is too small, the device has a poor effect of suppressing direct source-to-drain tunneling, resulting in an increase in a leakage current, and at the same time, increasing a difficulty in a process of manufacturing a bottom source region and a bottom drain region; and if the thickness of the first control gate is too large, a bottom parasitic capacitance increases, and a frequency characteristic of the device becomes poor. Therefore, in a preferred embodiment, the thickness of the first control gate in the second direction is 5 nm to 200 nm.

In an embodiment, the first ions are P-type ions or N-type ions.

In an embodiment, the second ions are P-type ions or N-type ions.

Specifically, the P-type ion is a hydride, a fluoride, or a chloride of boron, and is specifically one or a combination of the following materials: B2H6, B4H10, B6H10, B10H14, B18H22, BF3, or Bcl3; and the N-type ion is a hydride or a fluoride of phosphorus and arsenic, and is specifically one or a combination of the following materials: phosphine, arsine, phosphorus pentafluoride, phosphorus trifluoride, arsenic pentafluoride, or arsenic trifluoride.

A channel region and a bottom Fin region (that is, the substrate 101) are undoped or lightly i-doped regions.

For an N-type device, the first source region 109 is N-type doped, and doping concentration thereof is approximately 1E18 cm⁻³ to 1E22 cm⁻³; the first drain region 110 is N-type doped, and doping concentration thereof is approximately 1E18 cm⁻³ to 1E22 cm⁻³; the second source region 107 is P-type doped, and doping concentration thereof is approximately 1E18 cm⁻³ to 1E22 cm⁻³; and the second drain region 108 is N-type doped, and doping concentration thereof is approximately 1E16 cm⁻³ to 1E21 cm⁻³.

For a P-type device, the first source region 109 is P-type doped, and doping concentration thereof is approximately 1E18 cm⁻³ to 1E22 cm⁻³; the first drain region 110 is P-type doped, and doping concentration thereof is approximately 1E18 cm⁻³ to 1E20 cm⁻³; the second source region 107 is N-type doped, and doping concentration thereof is approximately 1E18 cm⁻³ to 1E22 cm⁻³; and the second drain region 108 is P-type doped, and doping concentration thereof is approximately 1E16 cm⁻³ to 1E21 cm⁻³.

In the bottom U-shaped gate-all-around transistor device, a thickness of the second source region 107, a thickness of the second drain region 108, the doping concentration of the second source region 107, and the doping concentration of the second drain region 108 are important parameters for device design. If the thickness of the second source region 107 or the second drain region 108 is too small, an effect exerted by a bottom tunneling field-effect transistor on a total current is relatively small, and improvement to a sub-threshold swing characteristic of the device is limited. If the thickness of the second source region 107 or the second drain region 108 is too large, a difficulty in a process is increased, resulting in reduction in the uniformity and the reliability of the device. The doping concentration of the second source region 107 cannot be too low, and excessively low doping concentration leads to an increase in resistance of the second source region 107, and relatively low doping concentration reduces a tunneling probability of a bottom tunneling transistor. Consequently, band-to-band tunneling is more difficult to occur and a current decreases. The doping concentration of the second drain region 108 also needs to be controlled within a specific range. If the doping concentration is too low, resistance of the bottom drain region increases and a current decreases. If the doping concentration is too high, a bipolar effect of a channel of the TFET device is more obvious. Therefore, in a preferred embodiment, the thickness of the second source region 107 and/or the second drain region 108 is 5 nm to 50 nm. In a preferred embodiment, concentration of ions doped in the second source region 107 and/or the second drain region 108 is 1E16 cm⁻³ to 1E22 cm⁻³.

In an embodiment, a material of the second source region 107 and a material of the second drain region 108 are binary or ternary compounds from Group II-VI, III-V, or IV-IV.

In an embodiment, the material of the second source region 107 and the material of the second drain region 108 are Si, SiGe, or Ge.

In an embodiment, the gate-all-around MOSFET device further includes:
gate dielectric layers and control gates, where each of the gate dielectric layers wraps a part of a surface of each corresponding channel layer 103 and one of the gate dielectric layers covers the surface of the substrate 101 between the second source region 107 and the second drain region 108, the channel layers 103 are formed between the first source region 109 and the first drain region 110 and are arranged at intervals in a direction away from the substrate 101, each of the control gates covers a surface of each corresponding gate dielectric layer, the control gates include the first control gate, and when other control gates cover the surfaces of the gate dielectric layers,, the first control gate covers the surface of the gate dielectric layer on the surface of the substrate 101;
inner spacer 104 formed on the surfaces of the channel layers 103 between the first source region 109 and the gate dielectric layers and between the first drain region 110 and the gate dielectric layers;
a source metal layer 111, a gate metal layer 113, and a drain metal layer 112, where the source metal layer 111 and the drain metal layer 112 are respectively formed on a surface of the first source region 109 and a surface of the first drain region 110, and completely wrap the first source region 109 and the second source region 107 and completely wrap the first drain region 110 and the second drain region 108, respectively, and the gate metal layer 113 is formed at a top end of a top control gate;
an interlayer dielectric layer 114 covering surfaces of the source metal layer 111, the gate metal layer 113, the drain metal layer 112, and the inner spacer 104; and
several metal contact layers 115 penetrating the interlayer dielectric layer 114 and respectively connected to the source metal layer 111, the gate metal layer 113, and the drain metal layer 112.

According to an embodiment of the present invention, a manufacturing method for a bottom U-shaped gate-all-around transistor device is further provided, and the method is used to manufacture the bottom U-shaped gate-all-around transistor device according to any one of the foregoing embodiments of the present invention. The method includes the following steps:
S11: Form the gate-all-around MOSFET device, the second source region 107, and the second drain region 108, where the gate-all-around MOSFET device includes the substrate 101, the first source region 109, the first drain region 110, the first control gate, and the channel layers 103, the channel layers 103 include a first channel layer 103, the first channel layer 103 represents a channel layer 103 that is the closest to the substrate 101, the first control gate represents a control gate that is the closest to the substrate 101, the first source region 109 and the first drain region 110 are doped with the first ions, the second source region 107 and the second drain region 108 are respectively formed between the substrate 101 and the first source region 109 and between the substrate 101 and the first drain region 110, the second drain region 108 is doped with the first ions, and the second source region 107 is doped with the second ions; where a thickness of the first control gate 103 in the second direction is greater than thicknesses of other control gates 103 in the second direction, a height of a first surface of the second source region 107 and a height of a first surface of the second drain region 108 in the second direction are not higher than a bottom surface of the first channel layer 103, and a height of a second surface of the second source region 107 and a height of a second surface of the second drain region 108 in the second direction are not lower than the surface of the substrate 101 between the second source region 107 and the second drain region 108. A formed bottom U-shaped gate-all-around transistor device is shown in FIG. 1 or FIG. 2.

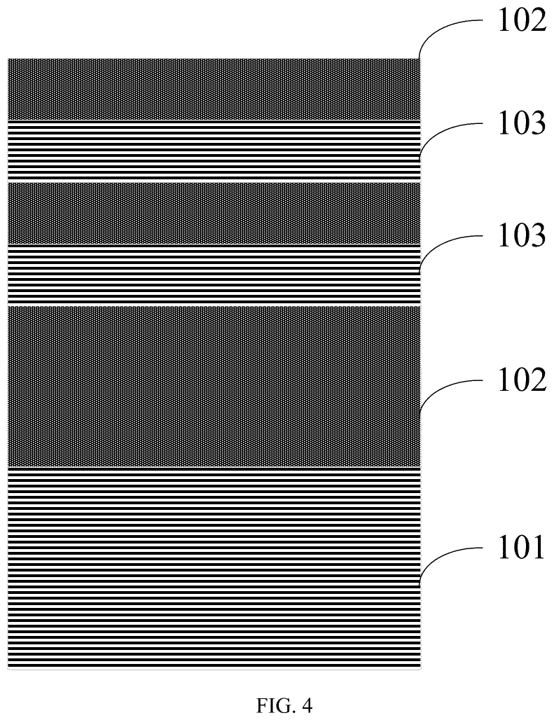

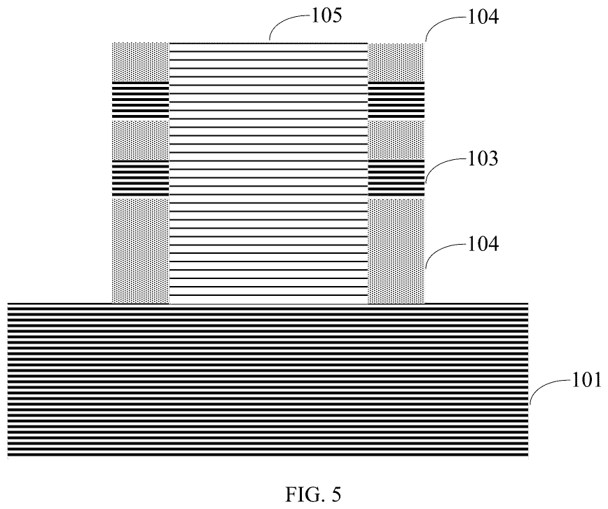

In an embodiment, in step S11, the forming the gate-all-around MOSFET device, the second source region 107, and the second drain region 108 specifically includes the following steps:
S111: Provide the substrate 101.
S112: Form sacrificial layers 102 and the channel layers 103, where the sacrificial layers 102 and the channel layers 103 are alternately stacked on the substrate 101, a thickness of the first sacrificial layer 102 is greater than a thickness of another sacrificial layer 102, the first sacrificial layer 102 represents a sacrificial layer 102 that is the closest to the substrate 101, that is, the first sacrificial layer 102 is directly formed on the substrate 101, as shown in FIG. 4. In the technical solution provided in the present invention, the thickness of the first sacrificial layer 102 is set to be greater than the thickness of the another sacrificial layer 102, so that after a subsequent step S118, that is, remove the dummy gate structure 105 and release the channel layers 103, original space in which the first sacrificial layer 102 is located may be used as space for subsequently filling the first control gate, and original space in which the another sacrificial layer 102 is located may be used as space for subsequently filling another control gate, so that the thickness of the first control gate is greater than the thickness of the another control gate. The formed sacrificial layers 102 and channel layers 103 are stacked Si/SiGe layers with a crystal orientation of <100>.
S113: Etch the sacrificial layers 102 and the channel layers 103 to form a fin structure, control a length of a channel of the device to be approximately 50 nm to 100 nm, and control a thickness of an over-etching region of the device to be 5 nm to 50 nm.
S114: Form a dummy gate structure 105, and etch both ends of the sacrificial layers 102 in the first direction to form a cavity of an inner spacer 104. A method for growing the dummy gate structure 105 is selected from one of the following methods: atomic layer deposition, chemical vapor deposition, and physical vapor deposition. In a specific example, a thickness of the dummy gate structure 105 is approximately 50 nm.
S115: Form the inner spacer 104, where the inner spacer 104 is formed in the cavity of the inner spacer 104. A device structure obtained after step S115 is shown in FIG. 5. Specifically, a material of the inner spacer 104 is selected from SiO2, Si3N4, or another low-K dielectric material. A method for growing the inner spacer 104 is selected from one of the following methods: atomic layer deposition, chemical vapor deposition, and physical vapor deposition. In a specific example, the inner spacer 104 is formed by depositing Si3N4 through LPCVD.
S116: Form the second source region 107 and the second drain region 108, where the second source region 107 and the second drain region 108 are respectively formed on both sides of the fin structure in the first direction, and optional disposing ranges of the second source region 107 and the second drain region 108 are limited and are specifically explained in subsequent descriptions of the present invention. In a specific example, the second drain region 108 is doped with As at concentration of approximately 1E18 cm⁻³. In a specific example, the second source region 107 is doped with B at concentration of approximately 1E21 cm⁻³.

In an implementation, a method for growing the second source region 107 and the second drain region 108 is selected from one of the following methods: in-situ epitaxy, atomic layer deposition, and chemical vapor deposition.

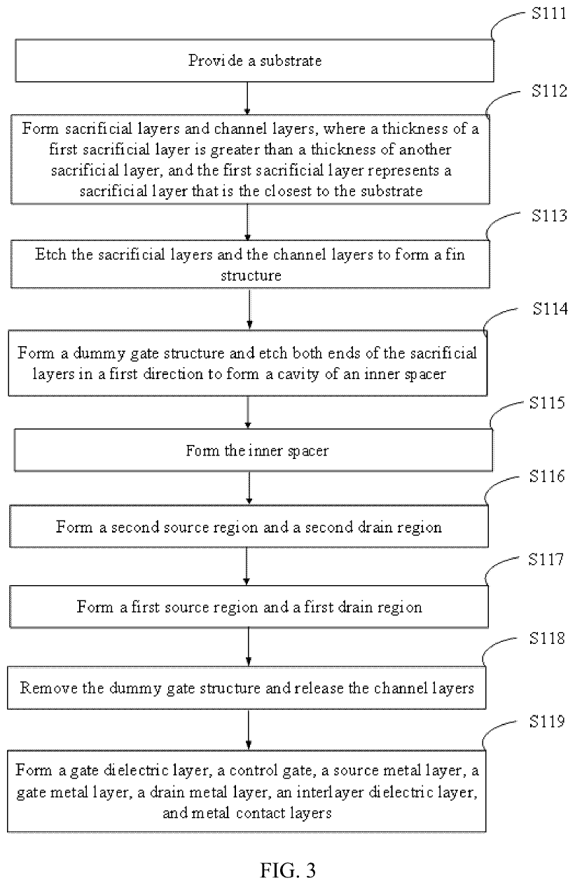

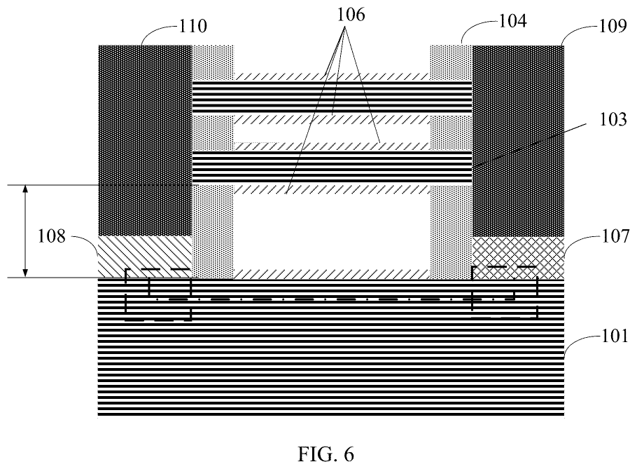

In another implementation, a method for highly doping the second source region 107 and the second drain region 108 is selected from one of the following methods: in-situ doping, ion implantation, and solid-state source doping.
S117: Form the first source region 109 and the first drain region 110, where the first source region 109 and the first drain region 110 are respectively formed at a top end of the second source region 107 and a top end of the second drain region 108. In a specific example, a material for source-drain epitaxy is selected from SiGe and Si:C. In a specific example, the first source region 109 and the first drain region 110 are doped with As at concentration of approximately 1E21 cm⁻³. After step S117, the method further includes: injecting impurities for activation (1050° C., 10 s).
S118: Remove the dummy gate structure 105 and release the channel layers 103. A device structure obtained after step S118 is shown in FIG. 6. It may be learned from FIG. 6 that in the technical solution provided in the present invention, a length of a bottom channel increases (where the length of the bottom channel is shown by a dash-dot path in the figure, and an increased channel length is shown by a dashed-line box).
S119: Form the gate dielectric layer, the control gates, the source metal layer 111, the gate metal layer 113, the drain metal layer 112, the interlayer dielectric layer 114, and the metal contact layers 115. A schematic flowchart of the manufacturing method of steps S111 to S119 is shown in FIG. 3. A material of the gate dielectric layer is selected from SiO2, Si3N4, or a high-K gate dielectric material. A method for growing the gate dielectric layer is selected from one of the following methods: conventional thermal oxidation, nitrogen-doped thermal oxidation, atomic layer deposition, or chemical vapor deposition. In a specific example, one gate dielectric layer is deposited through ALD, where the gate dielectric layer is HfO2, and a thickness is 1 nm to 5 nm. A material of the control gates is deposited through PEALD, where the material of the control gates is a TiN layer whose thickness is 50 nm to 200 nm.

In an embodiment, in step S112, the thickness of the first sacrificial layer 102 is 5 nm to 200 nm, and the thickness of the another sacrificial layer 102 is 5 nm to 50 nm. As for step S113, in an implementation, if the substrate 101 on both sides of the fin structure in the first direction is not over-etched when the sacrificial layers 102 and the channel layers 103 are etched to form the fin structure, step S114 to step S119 are performed to form the gate-all-around MOSFET device, the second source region 107, and the second drain region 108.

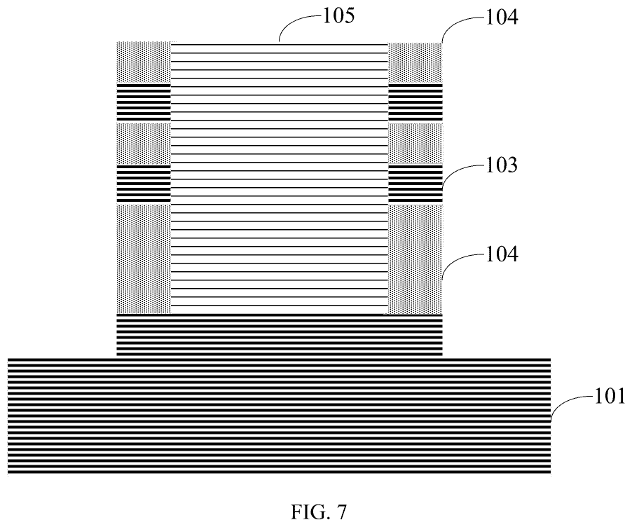

However, considering a relatively high process difficulty of the foregoing implementation, the present invention provides another implementation: In step S113, if the substrate 101 on both sides of the fin structure in the first direction is over-etched (as shown in FIG. 7) when the sacrificial layers 102 and the channel layers 103 are etched to form the fin structure,
before step S117, that is, form the second source region 107 and the second drain region 108, the method further includes:
forming a first epitaxial layer 106, where the first epitaxial layer 106 is formed on both sides of the fin structure in the first direction, and a height of the first epitaxial layer 106 in the second direction is not lower than a height of the substrate 101 between the second source region 107 and the second drain region 108. In a specific example, a material of the first epitaxial layer 106 is undoped Si.

The second source region 107 and the second drain region 108 are separately formed on a surface of the first epitaxial layer 106. Specifically, the material of the first epitaxial layer 106 is Si, which is the same as the material of the substrate 101.

In an implementation, the height of the first epitaxial layer 106 in the second direction is equal to the height of the substrate 101 between the second source region 107 and the second drain region 108. For a device structure, reference may be made to FIG. 5.

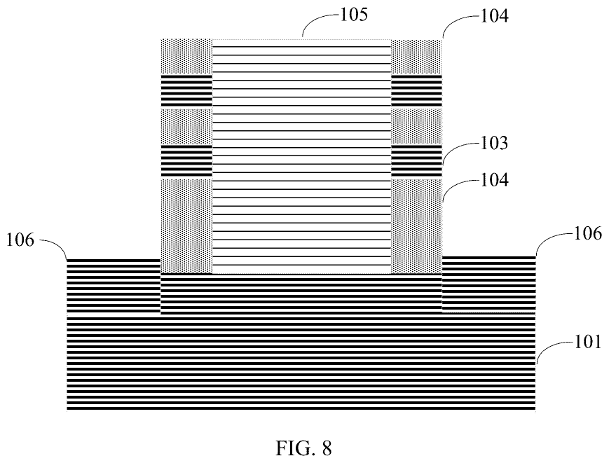

In another implementation, the height of the first epitaxial layer 106 in the second direction is higher than the height of the substrate 101 between the second source region 107 and the second drain region 108, as shown in FIG. 8. When the thickness of the second source region 107 and the thickness of the second drain region 108 are fixed, an epitaxial height of the first epitaxial layer 106 is adapted to the height from a bottom surface of the first channel layer 103 to the substrate 101, that is, the thickness of the first sacrificial layer 102.

In this implementation, other process steps after step S113 are similar to subsequent process steps of the foregoing implementation of not over-etching. Details are not described again in this application.

Corresponding to an implementation in which the first epitaxial layer 106 has the same height as the substrate 101, for a device structure obtained after step S118, that is, remove the dummy gate structure 105 and release the channel layers 103, reference may be made to FIG. 6 (in FIG. 6, the length of the bottom channel is shown by a dash-dot path, and an increased channel length is shown by a dashed-line box). The height between arrows in FIG. 6 is an optional disposing range for the second source region 107 and the second drain region 108.

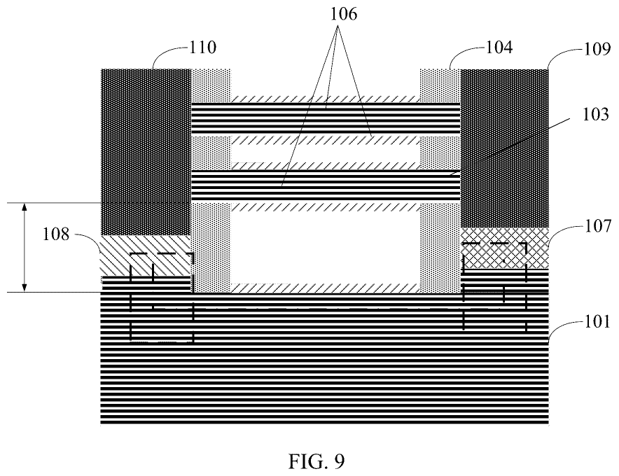

Corresponding to an implementation in which the first epitaxial layer 106 is higher than the substrate 101, a device structure obtained after step S118, that is, remove the dummy gate structure 105 and release the channel layers 103, may be shown in FIG. 9 (in FIG. 9, the length of the bottom channel is shown by a dash-dot path, and an increased channel length is shown by a dashed-line box). It can be learned that in this implementation, the length of the bottom channel of the device is longer than that in the first implementation (as shown in FIG. 6). The height between arrows in FIG. 9 is an optional disposing range for the second source region 107 and the second drain region 108.

In an embodiment, when the sacrificial layers 102 and the channel layers 103 are etched to form the fin structure, an over-etching thickness of the substrate 101 is controlled to range from 5 nm to 100 nm.

Step S116, that is, form the second source region 107 and the second drain region 108, specifically includes the following steps:
S1161: Form a patterned first mask layer, where the patterned first mask layer covers the second cavity, the dummy gate structure 105, and a surface of the inner spacer 104.
S1162: Fill the first cavity with a material of the second source region 107 to form the second source region 107, and remove the patterned first mask layer.
S1163: Form a patterned second mask layer, where the patterned second mask layer covers the second source region 107, the dummy gate structure 105, and the surface of the inner spacer 104.
S1164: Fill the second cavity with a material of the second drain region 108 to form the second drain region 108, and remove the patterned second mask layer.

Secondly, according to an embodiment of the present invention, an electronic device is further provided, including the bottom U-shaped gate-all-around transistor device according to any one of the foregoing embodiments of the present invention.

In addition, according to an embodiment of the present invention, a manufacturing method for an electronic device is further provided, including the manufacturing method for a bottom U-shaped gate-all-around transistor device according to any one of the foregoing embodiments of the present invention.

Finally, it should be noted that the foregoing embodiments are merely used to describe the technical solutions of the present invention, but are not intended to limit the technical solutions. Although the present invention is described in detail with reference to the foregoing embodiments, a person of ordinary skill in the art should understand that the technical solutions recorded in the foregoing embodiments can still be modified, or equivalent replacements can be made to some or all technical features in the technical solutions. However, these modifications or replacements do not make the essence of the corresponding technical solutions depart from the scope of the technical solutions in the embodiments of the present invention.

1. A bottom U-shaped gate-all-around transistor device, comprising:
a gate-all-around MOSFET device comprising a substrate, a first source region, a first drain region, a first control gate, and channel layers, wherein the first source region and the first drain region are arranged in a first direction, the first source region and the first drain region are doped with first ions, the first direction represents a direction parallel to a surface of the substrate, the channel layers comprise a first channel layer, the first channel layer represents a channel layer that is the closest to the substrate, and the first control gate represents a control gate that is the closest to the substrate; and
a second source region and a second drain region, wherein the second source region is formed between the substrate and the first source region, the second drain region is formed between the substrate and the first drain region, the second drain region is doped with the first ions, the second source region is doped with second ions, and a type of the first ion is different from a type of the second ion; wherein
a thickness of the first control gate in a second direction is greater than thicknesses of other control gates in the second direction, a height of a first surface of the second source region and a height of a first surface of the second drain region in the second direction are not higher than a bottom surface of the first channel layer, a height of a second surface of the second source region and a height of a second surface of the second drain region in the second direction are not lower than the surface of the substrate between the second source region and the second drain region, and the second direction is perpendicular to the first direction.

2. The bottom U-shaped gate-all-around transistor device according to claim 1, wherein a length of a channel of the bottom U-shaped gate-all-around transistor device is 5 nm to 100 nm.

3. The bottom U-shaped gate-all-around transistor device according to claim 2, wherein the thickness of the first control gate in the second direction is 5 nm to 200 nm.

4. The bottom U-shaped gate-all-around transistor device according to claim 3, wherein a thickness of the second source region and/or the second drain region in the second direction is 5 nm to 50 nm.

5. The bottom U-shaped gate-all-around transistor device according to claim 4, wherein the gate-all-around MOSFET device further comprises:
gate dielectric layers and control gates, wherein each of the gate dielectric layers wraps a part of a surface of each corresponding channel layer and one of the gate dielectric layers covers the surface of the substrate between the second source region and the second drain region, the channel layers are formed between the first source region and the first drain region and are arranged at intervals in a direction away from the substrate, each of the control gates covers a surface of each corresponding gate dielectric layer, the control gates comprise the first control gate, and when other control gates cover the surfaces of the gate dielectric layers, the first control gate covers the surface of the gate dielectric layer on the surface of the substrate;
inner spacer formed on the surfaces of the channel layers between the first source region and the gate dielectric layers and between the first drain region and the gate dielectric layers;
a source metal layer, a gate metal layer, and a drain metal layer, wherein the source metal layer and the drain metal layer are respectively formed on a surface of the first source region and a surface of the first drain region, and completely wrap the first source region and the second source region and completely wrap the first drain region and the second drain region, respectively, and the gate metal layer is formed at a top end of a top control gate;
an interlayer dielectric layer covering a surface of the source metal layer, a surface of the gate metal layer, a surface of the drain metal layer, and a surface of the inner spacer; and
several metal contact layers penetrating the interlayer dielectric layer and respectively connected to the source metal layer, the gate metal layer, and the drain metal layer.

6. A manufacturing method for a bottom U-shaped gate-all-around transistor device, used to manufacture the bottom U-shaped gate-all-around transistor device according to claim 1, and comprising:
forming the gate-all-around MOSFET device, the second source region, and the second drain region, wherein the gate-all-around MOSFET device comprises the substrate, the first source region, the first drain region, the first control gate, and the channel layers, the channel layers comprise a first channel layer, the first channel layer represents a channel layer that is the closest to the substrate, the first control gate represents a control gate that is the closest to the substrate, the first source region and the first drain region are doped with the first ions, the second source region and the second drain region are respectively formed between the substrate and the first source region and between the substrate and the first drain region, the second drain region is doped with the first ions, and the second source region is doped with the second ions; wherein
a thickness of the first control gate in the second direction is greater than thicknesses of other control gates in the second direction, a height of a first surface of the second source region and a height of a first surface of the second drain region in the second direction are not higher than a bottom surface of the first channel layer, and a height of a second surface of the second source region and a height of a second surface of the second drain region in the second direction are not lower than the surface of the substrate between the second source region and the second drain region.

7. The manufacturing method for a bottom U-shaped gate-all-around transistor device according to claim 6, wherein the forming the gate-all-around MOSFET device, the second source region, and the second drain region specifically comprises:
providing the substrate;
forming sacrificial layers and the channel layers, wherein the sacrificial layers and the channel layers are alternately stacked on the substrate, a thickness of a first sacrificial layer is greater than a thickness of another sacrificial layer, and the first sacrificial layer represents a sacrificial layer that is the closest to the substrate;
etching the sacrificial layers and the channel layers to form a fin structure;
forming a dummy gate structure and etching both ends of the sacrificial layers in the first direction to form a cavity of an inner spacer;
forming the inner spacer, wherein the inner spacer is formed in the cavity of the inner spacer;
forming the second source region and the second drain region, wherein the second source region and the second drain region are respectively formed on both sides of the fin structure in the first direction;
forming the first source region and the first drain region, wherein the first source region and the first drain region are respectively formed at a top end of the second source region and a top end of the second drain region;
removing the dummy gate structure and releasing the channel layers; and
forming the gate dielectric layer, the control gates, the source metal layer, the gate metal layer, the drain metal layer, the interlayer dielectric layer, and the metal contact layers.

8. The manufacturing method for a bottom U-shaped gate-all-around transistor device according to claim 7, wherein the thickness of the first sacrificial layer is 5 nm to 200 nm, and the thickness of the another sacrificial layer is 5 nm to 50 nm.

9. The manufacturing method for a bottom U-shaped gate-all-around transistor device according to claim 8, wherein if the substrate on both sides of the fin structure in the first direction is over-etched when the sacrificial layers and the channel layers are etched to form the fin structure, before the forming the second source region and the second drain region, the method further comprises:
forming a first epitaxial layer, wherein the first epitaxial layer is formed on both sides of the fin structure in the first direction, and a height of the first epitaxial layer in the second direction is not lower than a height of the substrate between the second source region and the second drain region; wherein
the second source region and the second drain region are separately formed on a surface of the first epitaxial layer.

10. The manufacturing method for a bottom U-shaped gate-all-around transistor device according to claim 9, wherein when the sacrificial layers and the channel layers are etched to form the fin structure, an over-etching thickness of the substrate is controlled to range from 5 nm to 100 nm.

11. An electronic device, comprising the bottom U-shaped gate-all-around transistor device according to claim 1.

12. (canceled)

13. The manufacturing method for a bottom U-shaped gate-all-around transistor device according to claim 6, wherein a length of a channel of the bottom U-shaped gate-all-around transistor device is 5 nm to 100 nm.

14. The manufacturing method for a bottom U-shaped gate-all-around transistor device according to claim 6, wherein the thickness of the first control gate in the second direction is 5 nm to 200 nm.

15. The manufacturing method for a bottom U-shaped gate-all-around transistor device according to claim 6, wherein a thickness of the second source region and/or the second drain region in the second direction is 5 nm to 50 nm.

16. The manufacturing method for a bottom U-shaped gate-all-around transistor device according to claim 6, wherein the gate-all-around MOSFET device further comprises:
gate dielectric layers and control gates, wherein each of the gate dielectric layers wraps a part of a surface of each corresponding channel layer and one of the gate dielectric layers covers the surface of the substrate between the second source region and the second drain region, the channel layers are formed between the first source region and the first drain region and are arranged at intervals in a direction away from the substrate, each of the control gates covers a surface of each corresponding gate dielectric layer, the control gates comprise the first control gate, and when other control gates cover the surfaces of the gate dielectric layers, the first control gate covers the surface of the gate dielectric layer on the surface of the substrate;
Inner spacer formed on the surfaces of the channel layers between the first source region and the gate dielectric layers and between the first drain region and the gate dielectric layers;
a source metal layer, a gate metal layer, and a drain metal layer, wherein the source metal layer and the drain metal layer are respectively formed on a surface of the first source region and a surface of the first drain region, and completely wrap the first source region and the second source region and completely wrap the first drain region and the second drain region, respectively, and the gate metal layer is formed at a top end of a top control gate;
an interlayer dielectric layer covering a surface of the source metal layer, a surface of the gate metal layer, a surface of the drain metal layer, and a surface of the inner spacer; and
several metal contact layers penetrating the interlayer dielectric layer and respectively connected to the source metal layer, the gate metal layer, and the drain metal layer.

17. The electronic device according to claim 11, wherein a length of a channel of the bottom U-shaped gate-all-around transistor device is 5 nm to 100 nm.

18. The electronic device according to claim 11, wherein the thickness of the first control gate in the second direction is 5 nm to 200 nm.

19. The electronic device according to claim 11, wherein a thickness of the second source region and/or the second drain region in the second direction is 5 nm to 50 nm.

20. The electronic device according to claim 11, wherein the gate-all-around MOSFET device further comprises:
gate dielectric layers and control gates, wherein each of the gate dielectric layers wraps a part of a surface of each corresponding channel layer and one of the gate dielectric layers covers the surface of the substrate between the second source region and the second drain region, the channel layers are formed between the first source region and the first drain region and are arranged at intervals in a direction away from the substrate, each of the control gates covers a surface of each corresponding gate dielectric layer, the control gates comprise the first control gate, and when other control gates cover the surfaces of the gate dielectric layers, the first control gate covers the surface of the gate dielectric layer on the surface of the substrate;
inner spacer formed on the surfaces of the channel layers between the first source region and the gate dielectric layers and between the first drain region and the gate dielectric layers;
a source metal layer, a gate metal layer, and a drain metal layer, wherein the source metal layer and the drain metal layer are respectively formed on a surface of the first source region and a surface of the first drain region, and completely wrap the first source region and the second source region and completely wrap the first drain region and the second drain region, respectively, and the gate metal layer is formed at a top end of a top control gate;
an interlayer dielectric layer covering a surface of the source metal layer, a surface of the gate metal layer, a surface of the drain metal layer, and a surface of the inner spacer; and
several metal contact layers penetrating the interlayer dielectric layer and respectively connected to the source metal layer, the gate metal layer, and the drain metal layer.
